(19) United States
(12) Patent Application Publication
(10) Pub. No.: US 2026/0221804 A1
(43) Pub. Date: Jul. 30, 2026

(54) METHOD, APPARATUS, AND SYSTEM FOR PREDICTING PERFORMANCE DEGRADATION OF A DISTRIBUTION TRANSFORMER

(71) Applicant: UBICQUIA, INC., FORT LAUDERDALE, FL (US)

(72) Inventors: Jow H. Ortiz, Coral Springs, FL (US); Gustavo Dario Leizerovich, Aventura, FL (US); Samuel Leonard Holden, Montreal (CA)

(21) Appl. No.: 19/420,725

(22) Filed: Dec. 15, 2025

Related U.S. Application Data
(60) Provisional application No. 63/734,743, filed on Dec. 16, 2024.

(51) Int. Cl. H02J 13/18; G01R 19/02; G01R 19/25; G01R 31/52; G01R 31/62; H02J 13/12; H02J 13/13

(52) U.S. Cl. CPC H02J 13/18; G01R 19/02; G01R 19/2513; G01R 31/52; G01R 31/62; H02J 13/12; H02J 13/1331

(57) ABSTRACT

A system for monitoring a distribution transformer includes a monitoring device and a processor. The monitoring device is collocated with the transformer and configured to detect voltages at one or more secondary terminals of the transformer and generate data signals representative of the detected secondary terminal voltages. The processor is operable in accordance with stored operating instructions to: receive the data signals from the monitoring device; determine, from the data signals, whether a magnitude of a voltage at a secondary terminal abruptly increased; when such an abrupt voltage increase occurred, determine, from the data signals, whether the magnitude of the voltage at the secondary terminal remained at the increased magnitude for at least a threshold period of time; and determine that performance of the transformer has degraded when the magnitude of the voltage at the secondary terminal remained at the increased magnitude for at least the threshold period of time.

### CROSS-REFERENCE TO RELATED APPLICATIONS

The present application claims the benefit of and priority upon U.S. Provisional Ser. No. 63/734,743 , which was filed on Dec. 16, 2024, and is incorporated herein by this reference as if fully set forth herein..

### TECHNICAL FIELD

The present disclosure relates generally to fault monitoring and detection methods and systems in electrical distribution systems. More particularly, but not exclusively, the present disclosure relates to predicting performance degradation of a distribution transformer in an electrical distribution system.

### BACKGROUND

Distribution transformers are parts of an electrical power distribution system infrastructure. The electrical gid includes power sources (e.g., power plants, solar farms, wind farms, hydropower turbines, etc.), power lines, transformers and other devices for power generation, power transmission, and power distribution/delivery. A power source generates or otherwise sources power, which is then transmitted along high voltage (HV) power lines of the electrical power transmission system infrastructure for long distances. Typical voltages found on HV transmission lines range from 69 kilovolts (kV) to 800 kV or more. The HV power signals are stepped down to medium voltage (MV) power at substations within the power transmission system and then stepped down further to low voltage (LV) levels by distribution transformers within the power distribution system. Thus, distribution transformers perform the function of stepping down the voltage from MV to LV for distribution over LV power lines. LV power lines typically carry power signals having voltages ranging from about 100 V to about 600 V to customer premises.

In the United States, distribution transformers typically feed anywhere from one to ten homes or low-to-medium use business, depending upon the concentration of the customers and the load capability of the transformer. Larger commercial and industrial business often include one or more distribution transformers on site for their own operations. A power distribution system for a given area may include many distribution transformers. Thus, the monitoring, maintenance, and replacement costs for distribution transformers can be a significant factor in the cost of power distribution.

A number of factors adversely affect the life and operation of a distribution transformer. One such factor is transformer overloading. A challenge to the efficient maintenance of a distribution transformer is that an overload cannot be detected and monitored directly. While monitoring devices are already used to monitor various transformer parameters, such devices and the systems that process their data are informative, not predictive.

### SUMMARY

According to one exemplary embodiment of the present disclosure, a method for predicting performance degradation of a distribution transformer in an electrical distribution system is performed by a processor positioned either at a remote location, such as in a cloud environment, or within a transformer monitoring device collocated with the distribution transformer. As used throughout this disclosure and the appended claims, the term “processor” refers to a single processor, a set of processors, a computing system, a server, a cloud server instance, a set of distributed processors, or any single device or set of devices capable of executing computer-readable instructions. When the processor is located remotely from the monitoring device (including when the processor resides in a cloud environment), the monitoring device is further configured to communicate data signals to the processor. Such communication of data signals may be through a wireless interface (such as an LTE or 5G modem), a wired interface (such as an Ethernet or cable modem), an optical interface (such as fiber optic modem or optical network terminal), or by any other known or future developed communication means.

According to the exemplary method, the processor receives data signals representative of voltages at one or more secondary terminals of the distribution transformer. The data signals may be representative of peak or root mean square (RMS) voltages at the secondary terminal(s) and be received over days, weeks, months, and years at preset or configurable reporting time intervals (e.g., every N minutes or every M hours, where N and M are integers) programmed into the monitoring device. Where the data signals are received from a transformer monitoring device located remotely from the processor performing analysis of the data signals, the monitoring device communicates the data signals to the processor at the reporting time intervals. Where the processor performing analysis of the data signals is integrated into the monitoring device, the processor may receive the data signals from an analog-to-digital converter that converts the raw analog signals output from voltage sensor(s) into the data signals.

From the received data signals, the processor determines whether a magnitude of a voltage at a secondary terminal of the one or more secondary terminals abruptly increased and, if so, remained at the increased magnitude for at least a threshold period of time (e.g., at least thirty minutes, sixty minutes, six hours, twelve hours, or twenty-four hours). When after abruptly increasing, the voltage at the secondary terminal remains at the increased magnitude for at least the threshold period of time, the processor determines that the performance of the distribution transformer has degraded and may optionally communicate a notification of such performance degradation to a user (e.g., a utility or other operator (e.g., commercial or industrial entity that owns or operates its own distribution transformers)) that owns or controls the distribution transformer. According to an exemplary embodiment, the processor determines that the voltage at the secondary terminal has abruptly increased if it has increased by at least ten percent within a one-hour to ten-hour window of time and, more preferably, within a two-hour to four-hour window of time.

According to an alternative exemplary embodiment, the processor may analyze other operational parameters of the distribution transformer to confirm that the abrupt increase in secondary terminal voltage is predictive of performance degradation of the distribution transformer. For example, the processor may receive additional data signals representative of voltages (e.g., RMS or peak) at a primary terminal of the distribution transformer, such as from the transformer monitoring device or from one or more sensors forming a part thereof or being physically or wirelessly coupled thereto. From the additional data signals, the processor may determine whether a magnitude of a voltage at the primary terminal abruptly increased within a predetermined time window (e.g., within a few seconds) prior to the abrupt increase in the voltage at the secondary terminal. In other words, the processor may determine whether the abrupt increase in the secondary terminal voltage was due to an abrupt increase in the primary terminal voltage. If the magnitude of the voltage at the primary terminal did not abruptly increase within the predetermined time window prior to the abrupt increase in the voltage at the secondary terminal, then the processor may confirm that the performance of the distribution transformer has degraded.

Alternatively or additionally, the processor may analyze other non-voltage operational parameters of the distribution transformer (such as, for example, oil pressure, oil temperature, primary winding temperature, secondary winding temperature, and/or secondary current) to determine whether a magnitude of one or more of those parameters had an abrupt change (e.g., increase) within a time window (e.g., less than thirty minutes and possibly even less than a minute) of the abrupt increase in the voltage at the secondary terminal. When the processor determines that the magnitude of at least one other operational parameter abruptly increased within the predetermined time window of the abrupt increase in the voltage at the secondary terminal, the processor may confirm that performance of the distribution transformer has degraded (and the distribution transformer may be headed toward failure). When analyzing magnitudes of operational parameters other than voltage and current, the processor may compute or receive from the monitoring device average magnitude values over a time period (e.g., minutes or hours) to account for any transient activity and, when analyzing voltage and current, the processor may compute or receive from the monitoring device RMS values.

According to a further exemplary embodiment of the present disclosure, a system for monitoring a distribution transformer includes a monitoring device and a processor. The monitoring device is collocated with the distribution transformer, but the processor may be collocated with the monitoring device (e.g., within or otherwise forms part of the monitoring device) or be located remotely from the monitoring device and, for example, reside in a cloud environment. When the processor is located remotely from the monitoring device, the monitoring device is configured to (a) detect voltages at one or more secondary terminals of the distribution transformer and (b) generate data signals representative of the detected secondary terminal voltages. The processor is operable in accordance with stored operating instructions to, among other things: (a) receive the data signals (e.g., from the monitoring device where the processor is remote or from an analog-to-digital converter of the monitoring device where the processor forms part of the monitoring device); (b) determine, from the received data signals, whether a magnitude of a voltage at a secondary terminal of the one or more secondary terminals abruptly increased (e.g., within a one-hour to ten-hour window of time or, more acutely, within a two-hour to four-hour window of time); (c) when the magnitude of a voltage at a secondary terminal abruptly increased, determine, from the received data signals, whether the magnitude of the voltage at the secondary terminal remained at the increased magnitude for at least a threshold period of time (e.g., from thirty minutes to twenty-four hours or more but more preferably for at least twelve hours, such as from twelve to twenty-four hours); and (d) determine that performance of the distribution transformer has degraded when the magnitude of the voltage at the secondary terminal remained at the increased magnitude for at least the threshold period of time. Responsive to determining the performance degradation, the processor may optionally communicate a notification to a user (e.g., a utility or other operator (e.g., commercial or industrial entity that owns or operates its own distribution transformers)) to inform that performance of the distribution transformer has degraded.

According to a further exemplary embodiment of the distribution transformer monitoring system, the monitoring device is further configured to detect voltages at a primary terminal of the distribution transformer and generate second data signals representative of the detected primary terminal voltages. In this embodiment, the processor may be further operable in accordance with stored operating instructions to receive the primary terminal voltage data signals and determine, from the received primary terminal voltage data signals, whether a magnitude of a voltage at the primary terminal abruptly increased within a predetermined time window prior to the abrupt increase in the voltage at the secondary terminal. When the magnitude of the voltage at the primary terminal did not abruptly increase within the predetermined time window prior to the abrupt increase in the voltage at the secondary terminal, the processor confirms that performance of the distribution transformer has degraded.

According to yet another exemplary embodiment of the distribution transformer monitoring system, the monitoring device is further configured to detect at least one other operational parameter of the distribution transformer (such as, for example, oil pressure, oil temperature, primary winding temperature, secondary winding temperature, and/or secondary current) and generate data signals representative of the at least one other operational parameter. In this embodiment, the processor may be further operable in accordance with stored operating instructions to receive the operational parameter data signals and determine, from the received operational parameter data signals, whether a magnitude of at least one other operational parameter (i.e., other than a secondary terminal voltage) abruptly increased within the time window of the abrupt increase in the voltage at the secondary terminal. When the magnitude of at least one other operational parameter abruptly increased within the time window of the abrupt increase in the voltage at the secondary terminal, the processor confirms that performance of the distribution transformer has degraded.

According to a further exemplary embodiment of the present disclosure, an apparatus for monitoring a distribution transformer is configured to be collocated with the distribution transformer and includes at least one voltage sensor, one or more analog-to-digital converters, and a processor. The voltage sensor (or each voltage sensor, where there are two or more) is configured to detect voltages at a secondary terminal of the distribution transformer and generate signals (e.g., voltages) representative of the detected secondary terminal voltage. The analog-to-digital converter (or each analog-to-digital converter, where there are two or more) converts the signals generated by the voltage sensor (or generated by a respective voltage sensor) into data signals. The processor is operable in accordance with stored operating instructions to, among other things: (a) receive the data signals from the analog-to-digital converter; (b) determine, from the received data signals, whether the magnitude of a voltage at a secondary terminal of the one or more secondary terminals abruptly increased (e.g., within a one-hour to ten-hour window of time or, more acutely, within a two-hour to four-hour window of time); (c) when the magnitude of a voltage at a secondary terminal abruptly increased, determine, from the received data signals, whether the magnitude of the voltage at the secondary terminal remained at the increased magnitude for at least a threshold period of time (e.g., from thirty minutes to twenty-four hours or more but more preferably for at least twelve hours, such as from twelve to twenty-four hours); and (d) determine that performance of the distribution transformer has degraded when the magnitude of the voltage at the secondary terminal remained at the increased magnitude for at least the threshold period of time. Responsive to determining the performance degradation, the processor may optionally communicate a notification to a user (e.g., a utility or other operator (e.g., commercial or industrial entity that owns or operates its own distribution transformers)) to inform that performance of the distribution transformer has degraded. The processor may also confirm its determination of a transformer performance degradation by analyzing primary terminal voltages and/or other operational parameters of the distribution transformer as disclosed above with respect to the distribution transformer monitoring system.

In some embodiments, a method for detecting at least a voltage deviation event associated with (e.g., within or proximate to) a distribution transformer such as a pad-mounted (padmount) or aerial distribution transformer or pole-mounted transformer may include monitoring output data or one or more output signals (such as one or more voltage or current signals or other distribution transformer operational parameters) and determining, by a processor operably coupled to the distribution transformer, whether the output data or output signal(s) substantially corresponds to one or more data signatures representing voltage deviation events or other events at or above a predetermined threshold indicative of a degradation and possibly even a potential failure of the distribution transformer. The processor may further communicate, via a communication interface, an alert to a local or a remote computing device when the output data or output signal(s) substantially corresponds to one of the data signatures.

In some embodiments, the processor can determine whether the output data substantially corresponds to one of a plurality of data signatures by determining whether an output voltage measured at a secondary voltage output of the distribution transformer is greater than or equal to a voltage threshold. When the output voltage is greater than or equal to the voltage threshold, the processor determines whether the output voltage remained greater than or equal to the voltage threshold for at least a threshold time period (e.g., thirty minutes, twenty-four hours, etc.).

In some embodiments, the processor communicates the alert to a remote computing device via the communication interface. The alert may include or be accompanied by the output data representative of the data signature (e.g., in chart, graph (e.g., waveform), or table format).

In some embodiments, the data signature and the voltage threshold correspond to abnormal variations in other distribution transformer operational parameters. Such other operational parameters may include at least one or more of oil temperature, distribution transformer tank or housing surface temperature, oil pressure, secondary current, or primary or secondary winding temperature.

In some embodiments, the data signature and the voltage threshold correspond to abnormal variations in other distribution transformer parameters within a predetermined time period of the secondary terminal voltage elevation event, including at least one or more of oil temperature, surface temperature, oil pressure, or current.

### BRIEF DESCRIPTION OF THE DRAWINGS

Non-limiting and non-exhaustive embodiments are described with reference to the following drawings, wherein like reference numerals refer to like parts throughout the various views unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings.

FIG. 1 illustrates a high level diagram of an exemplary electrical grid in accordance with some exemplary embodiments of the present disclosure.

FIG. 2A illustrates an exemplary pad-mounted distribution transformer with its hatch door open in accordance with some exemplary embodiments of the present disclosure.

FIG. 2B illustrates an exemplary apparatus for monitoring a distribution transformer, which is capable of sensing secondary voltages and other operational parameters of the distribution transformer, in accordance with some exemplary embodiments of the present disclosure.

FIG. 3A illustrates an exemplary pad-mounted distribution transformer with its hatch door open and the monitoring apparatus of FIG. 2 attached to an outside surface of a wall 153 of the transformer tank, in accordance with some exemplary embodiments of the present disclosure.

FIG. 3B illustrates the pad-mounted distribution transformer of FIG. 3A with its hatch door closed, in accordance with some exemplary embodiments of the present disclosure.

FIG. 4 illustrates block diagram of a portion of an electric distribution system containing multiple pad-mounted distribution transformers similar to the pad-mounted distribution transformer of FIG. 3A and further illustrates an exemplary cloud-based processor located remotely from the distribution transformers and providing a web-accessible application for viewing data and alerts communicated by the processor, where each distribution transformer has collocated therewith a monitoring device for detecting voltages at secondary terminals of the distribution transformer and for optionally detecting other operational parameters of the distribution transformer, in accordance with some exemplary embodiments of the present disclosure.

FIG. 5 is an electrical block diagram of an apparatus/monitoring device for monitoring operational parameters of a distribution transformer in accordance with some exemplary embodiments of the present disclosure.

FIG. 6 is a logic flow diagram of steps executed by a processor to predict performance degradation of a distribution transformer in accordance with some exemplary embodiments of the present disclosure.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring descriptions of the embodiments.

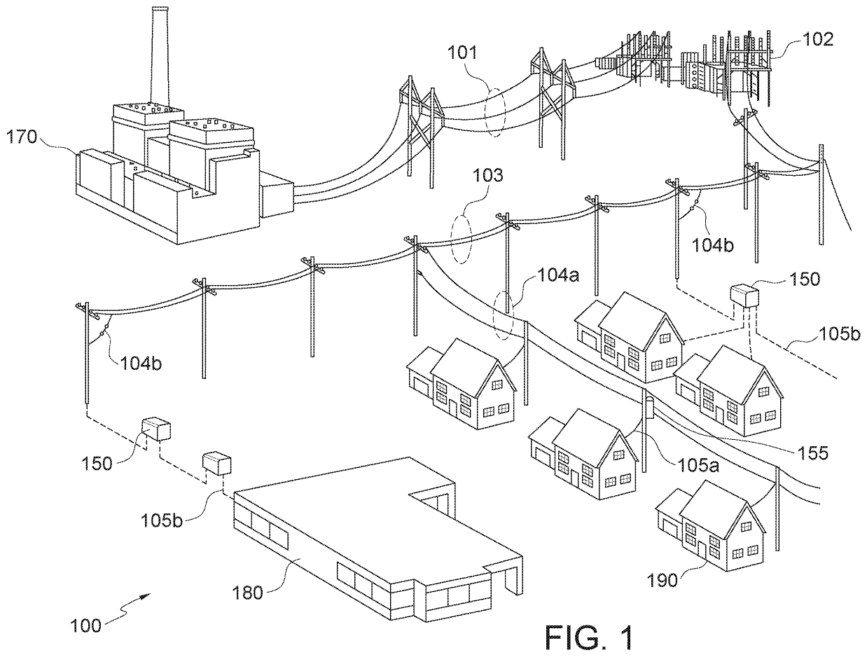

FIG. 1 illustrates a high level diagram of an exemplary electrical grid 100 in accordance with some exemplary embodiments of the present disclosure. The electrical grid 100 includes power generation, transmission, and distribution assets and resources. The electrical grid 100 can use any form of energy (like coal, diesel, wind, solar, hydroelectric, etc.) and convert it into electrical energy.

The electrical grid includes a power plant 170, step-up and step-down transformers, high voltage transmission lines 101 (more than 69 kV), substations 102 (including step-down transformers), medium voltage distribution lines (such as feeder lines 103 and lateral pull off lines 104a, 104b) (7 kV-100 kV), distribution transformers 150, 155, and low voltage distribution lines 105a, 105b (120-480V) for routing low voltage power to end users, such as commercial customers 180 and residential customers 190. The power plant 170 generates the power (which may be stepped up or stepped down in voltage, as necessary, through appropriate transformers). The high voltage transmission lines 101 transfer power to the various substations 102, which typically step the power down to medium voltage. The medium voltage power is transferred to the distribution transformers 150, 155 over the feeder lines 103 and lateral pull off lines 104a, 104b. The distribution transformers 150, 155 step the voltage down to appropriate levels suitable for the end customers, which can be either commercial 180 or residential 190.

Overhead lateral pull off lines 104a can be used with pole mounted or aerial distribution transformers 155 and underground lateral pull off lines 104b can be used with pad mounted distribution transformers 150. The pole mounted distribution transformers 155 and the pad mounted distribution transformers 150 each have high or medium voltage primary cables and lower voltage secondary cables going out to the end users. In the case of a pole mounted distribution transformer, an overhead secondary cable 105a can run from the pole mounted distribution transformer 155 to the residential end user 190. In the case of a pad mounted distribution transformer 150, an underground secondary cable 105b can run from the pad mounted transformer 150 to the commercial end user 180, for example. As shown, an underground secondary cable 105b can also run from a pad mounted transformer 150 to a residential end user 190.

In some embodiments, an apparatus 200 or other device installed within a hatch of a padmount transformer 150, on a housing of an aerial distribution transformer 155, or otherwise proximate to a distribution transformer is used to detect voltage deviation events and optionally other distribution transformer parameters associated with the distribution transformer. One embodiment can include programming an onboard processor with one or more output data signatures corresponding to voltage deviation or voltage step events or other events, such as aberrant oil temperature or surface oil temperature, current, or pressure readings. An alternative embodiment can include programming the server with output data signatures representing the particular events and sending raw output data to the server for event analysis and alarm generation. A priority schedule can also be set for various types of alarms based on the particular reading and the extent of deviations from normal readings. Other embodiments can combine the voltage step output data with other sensor data (such as photosensor data, oil temperature, pressure, current, etc.) to make appropriate assessments and alarms accordingly.

In some embodiments, a method for detecting at least a voltage deviation event associated with (e.g., within or proximate to) a distribution transformer such as a pad-mounted (padmount) or aerial distribution transformer or pole-mounted transformer may include monitoring output data or one or more output signals (such as one or more voltage or current signals or other distribution transformer parameters) and determining, by a processor operably coupled to the distribution transformer, whether the output data or output signal(s) substantially corresponds to one or more data signatures representing voltage deviation events or other events at or above a predetermined threshold indicative of a potential failure mode of the distribution transformer. The method may further include communicating, by the processor via a communication interface, an alert to a local or a remote computing device when the output data or output signal(s) substantially corresponds to one of the data signatures.

In some embodiments, the method can determine whether the output data substantially corresponds to one of a plurality of data signatures by determining, by the processor, whether an output voltage measured from a secondary voltage output of the distribution transformer is greater than or equal to a voltage threshold. When the output voltage is greater or equal to the voltage threshold the processor determines whether the output voltage remained greater than or equal to the voltage threshold for at least a threshold time period.

In some embodiments, the method communicates the alert to a remote computing device via the communication interface where the alert includes or is accompanied by the output data representative of the data signature.

In some embodiments the data signature and voltage threshold corresponds to abnormal variations in other distribution transformer parameters.

In some embodiments, the data signature and voltage threshold corresponds to abnormal variations in other distribution transformer parameters including at least one or more of oil temperature, surface temperature, oil pressure, or current. In some embodiments the data signature and voltage threshold corresponds to abnormal variations in other distribution transformer parameters including oil temperature, surface temperature, oil pressure, and current.

In some embodiments, the data signature and voltage threshold corresponds to abnormal variations in other distribution transformer parameters within a predetermined time period of the voltage deviation event, including at least one or more of oil temperature, surface temperature, oil pressure, or current.

In some embodiments, the method further includes determining, by the processor, whether an output voltage step measured from a primary voltage output of the distribution transformer is greater than or equal to threshold and sending the alert when the output voltage step indicates the potential failure mode in the distribution transformer.

In some embodiments, the method further includes determining, by the processor, whether an output voltage measured from a primary voltage output of the distribution transformer or other distribution transformers within a predetermined vicinity of the distribution has an output voltage at a respective primary voltage output that is greater than or equal to another voltage threshold not attributable to a voltage step of the primary voltage of the distribution transformer.

In some embodiments, the distribution transformer is a pad-mounted distribution transformer or a pole-mounted transformer.

In some embodiments, the distribution transformer is a pad-mounted distribution transformer or a pole-mounted transformer and the processor and the communication interface form part of a distribution transformer monitoring device.

In some embodiments, a distribution transformer monitoring device includes a housing configured to affix to a distribution transformer a communication interface, a non-transitory memory storing processor-executable instructions, and a processor, operably coupled to the monitoring device, the communication interface, and the memory. The processor is operable in accordance with the processor-executable instructions to perform the operations of monitoring output data, by the monitoring device positioned on, within or proximate to a housing of the distribution transformer for detecting at least a voltage deviation event associated with a distribution transformer, determining whether the output data substantially corresponds to one of a plurality of data signatures representing voltage deviation events at or above a predetermined threshold, and communicating by the processor via the communication interface al alert to a local or remote computing device when the output data substantially corresponds to one of the plurality of data signatures.

In some embodiments, the monitoring device determines whether the output data substantially corresponds to one of a plurality of data signatures by determining, by the processor, whether an output voltage measured from a secondary voltage output of the distribution transformer is greater than or equal to a voltage threshold and determining, by the processor, whether the output voltage remained greater than or equal to the voltage threshold for at least a threshold time period when the output voltage is greater or equal to the voltage threshold,.

In some embodiments the data signature and voltage threshold corresponds to abnormal variations in other distribution transformer parameters within a predetermined time period of the voltage deviation event, including at least one or more of oil temperature, surface temperature, oil pressure, or current.

In some embodiments, the processor is further configured to determine whether an output voltage step measured from a primary voltage output of the distribution transformer is greater than or equal to a threshold and sending the alert when the output voltage step indicates the potential failure mode in the distribution transformer.

In some embodiments, the processor is further configured to determine whether an output voltage measured from a primary voltage output of the distribution transformer or other distribution transformers within a predetermined vicinity of the distribution has an output voltage at a respective primary voltage output that is greater than or equal to another voltage threshold not attributable to a voltage step of the primary voltage of the distribution transformer.

In some embodiments, a distribution transformer monitoring system includes a device or other apparatus 200 for monitoring the distribution transformer 150 on, within or proximate to a housing of a distribution transformer, a communication interface, a non-transitory memory storing processor-executable instructions, and a processor, operably coupled to the monitoring device, the communication interface, and the memory. In some embodiments, the processor operates in accordance with processor-executable instructions to perform operations of monitoring output data of the distribution transformer for detecting at least a voltage deviation event associated with the distribution transformer, determining, by the processor, whether an output voltage measured from a secondary voltage output of the distribution transformer is greater than or equal to a voltage threshold, determining, by the processor, whether the output voltage remained greater than or equal to the voltage threshold for at least a threshold time period when the output voltage is greater or equal to the voltage threshold. In some embodiments the processor communicates via the communication interface, an alert to a local or remote computing device when the processor measures the output voltage from the secondary voltage output being greater than or equal to the voltage threshold for at least the threshold time period.

In some embodiments, the data signature and voltage threshold correspond to abnormal variations in other distribution transformer parameters within a predetermined time period of the voltage deviation event, including at least one or more of oil temperature, surface temperature, oil pressure, or current.

In some embodiments, the processor is further configured to determine whether an output voltage step measured from a primary voltage output of the distribution transformer is greater than or equal to threshold and sending the alert when the output voltage step indicates the potential failure mode in the distribution transformer.

In some embodiments, the processor is further configured to determine whether an output voltage measured from a primary voltage output of the distribution transformer or other distribution transformers within a predetermined vicinity of the distribution has an output voltage at a respective primary voltage output that is greater than or equal to another voltage threshold not attributable to a voltage step of the primary voltage of the distribution transformer.

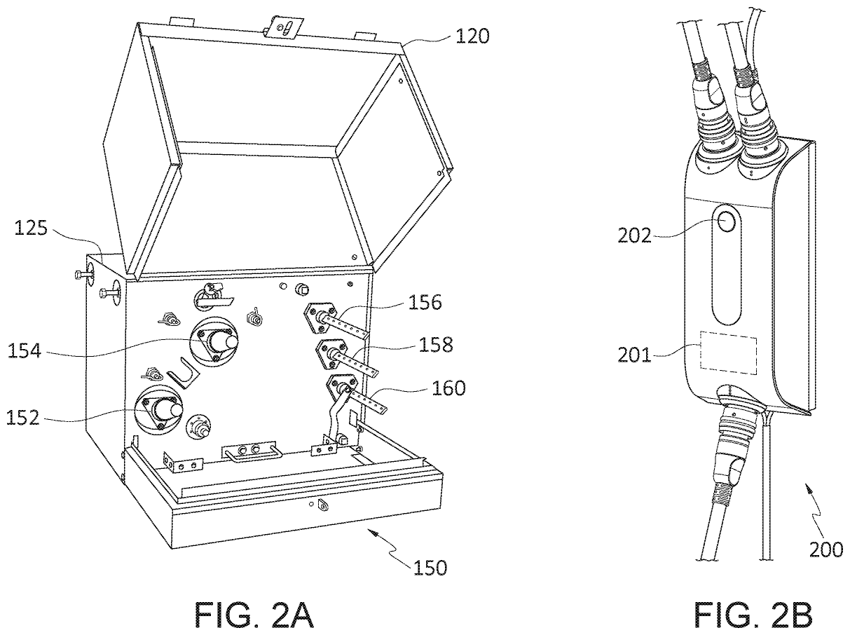

Referring to FIGS. 2A, 2B, 3A, 3B, 4, and 5, various views of an exemplary power transformer and a monitoring device 200 having one or more voltage sensors 201 and optionally other sensors (such as an accelerometer, an optical sensor 202, one or more temperature sensors, a pressure sensor, and current sensors) implemented or used along with a power transmission system which forms a part of an apparatus or system or method for detecting faults or voltage deviation events within the power transmission system or more particularly within a specific power transformer in the power transmission system is shown. More particularly, such a system can detect voltage deviation events or other anomalies based on signals obtained or derived from the monitoring device 200 or a Rogowski coil or in some embodiments from a combination of the Rogowski coil and other operational parameter sensors such as the optical sensor, or temperature sensors, pressure sensors, current meters, or other sensors that may be part of a monitoring device 200 or in communication with the monitoring device 200 or in communication with a remote computer system in communication with the monitoring device 200 and other sensors. Note that the parameter sensors contemplated within the embodiments are not limited to the sensors detailed here, but can include other sensors such as cameras, current transformers or voltmeters or other devices that measure current, voltage, impedance, Power Factor, motion, or other operational parameters useful in detecting potential faults or conditions requiring further review, monitoring, maintenance, repair, replacement or other desirable interventions prolonging the efficient useful life of such components and systems being monitored.

FIG. 2A illustrates an exemplary pad-mounted distribution transformer 150 with its hatch door open in accordance with some exemplary embodiments of the present disclosure. The pad-mounted distribution transformer 150 can include a high voltage primary input 152, a high voltage primary output 154, lower voltage secondary outputs 156, 160, and a lower voltage secondary neutral 158. Such a transformer 150 can be housed in a housing 125 having an openable and closeable hood or hatch door 120. The hatch door 120 provides easy access to the inputs, outputs and other components for installation and maintenance purposes. The hatch door 120 may be hinged or otherwise movably coupled to the main distribution transformer housing.

In some embodiments, the transformer 150 can include or have attached thereto a transformer monitoring device 200 as shown in one exemplary form in FIG. 2B, such as the UbiGrid® distribution transformer monitor plus (DTM+) available from Ubicquia, Inc. of Fort Lauderdale, Florida, U.S.A., which is a specialized hardware device that collects and measures various operational parameter information relating to operation of the distribution transformer 150. The transformer monitoring device 200 includes one or more voltage sensors 201 (e.g., voltage sensing circuits) and optionally other sensors, such as current sensors, temperature sensors, a pressure sensor, and an optical sensor 202, for example. The monitoring device 200 is typically a retrofit onto an aerial (e.g., pole top) or padmount transformer. An aerial (above ground) or padmount (below ground) transformer typically powers anywhere from 5-8 homes in the US and is the last voltage transition in stepping down voltage before it gets to the home or business. Standard positionings of the Rogowski coil assemblies 306, 308, 310 or the voltage sensing cables of the monitoring device 200 occur at the transformer bushings, but sometimes the assemblies/cables are attached directly onto the secondary electrical lines.

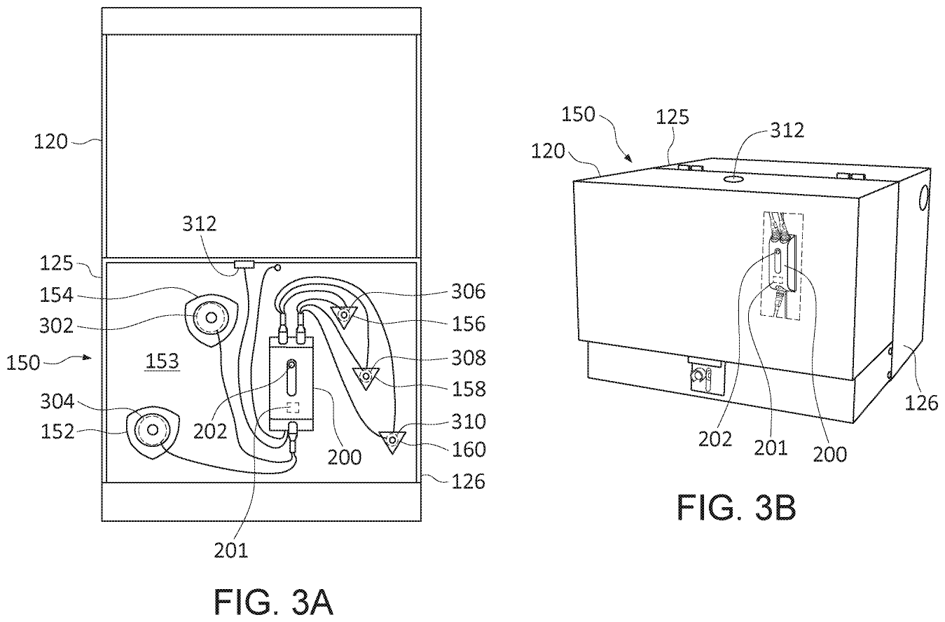

Referring to FIG. 3A, an exemplary smart transformer system includes the padmount transformer 150 of FIG. 1 together with a transformer monitoring device, such as the transformer monitoring device 200 of FIG. 2. The monitoring device 200 can further include Rogowski coils 302, 304 encircling the respective primary (high voltage) terminals 154, 152 and can provide additional information for analysis and fault detection in addition to telemetry data. The monitoring device 200 may also include current transformers or Rogowski coil assemblies 306, 308, 310 encircling the secondary terminals (low voltage side) 156, 158, and 160, respectively, of the transformer 100. FIG. 3B illustrates the hatch door 120 in a closed position closed against the sealed tank portion 126 of the main housing 125 of the transformer 150.

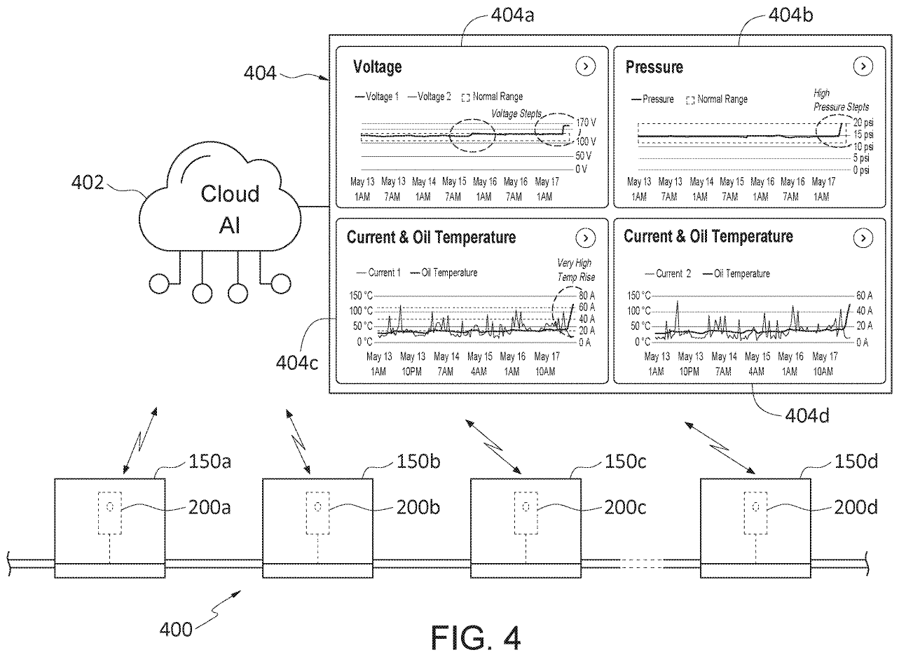

Due to the interior locations of the monitoring devices 200a-200d in an electrical distribution system 400 as shown in FIG. 4, the monitoring devices 200a-200d may present real-time and/or historical information about a particular transformer (150a, 150b, 150c, and 150d, respectively) to which it is attached or with which it is otherwise collocated, in addition to creating a vital ongoing information access point within a grid architecture. Each monitoring device 200a-200d can use an antenna connection and corresponding antenna 312 (as shown in FIG. 3A) to transmit such information to a remote processor 402 operating on a cloud network that can be a cloud AI that can provide analytics with respect to the grid and the components therein.

Referring again to the power distribution system 400 of FIG. 4, the embodiments herein using the parameter sensor(s) (in the form of Rogowski coil assemblies 306, 308, 310 on the secondary terminals 156, 158, 160 and optionally on the primary terminals 152, 154, the voltage sensor 201 and other sensors that may be included in a monitoring device 200) also enable an artificial intelligence (AI) based analysis system using a remote processor 402 or the monitoring device processor having such intelligence programmed within. The system 400 can include a plurality of pad-mounted transformers, such as pad-mounted transformers 150a-150d having a high/medium voltage primary input conductor and/or a high/medium voltage primary output conductor. In some embodiments, an analysis engine running on a remote processor 402, such as a cloud server, or the monitoring device processor can perform such analysis to monitor secondary and/or primary voltages and currents and generate time-based graphs therefor or thereof (such as oscillography waveforms), as well as monitor other transformer operational parameters of the transformer and generate graphs to show variations of those parameters over time. The graphs and other outputs of the processor 402 can be viewed on a panel/dashboard 404 of a web-based or mobile application. The additional data provided by the Rogowski coils and other sensors in such manner can further help classify or categorize the types of faults or performance degradations that are detected. Calculations and/or measurements can be done for some or each transformer 150a-150d in the system 400. All the data collected would be transmitted either in a wired fashion or via a wireless connection.

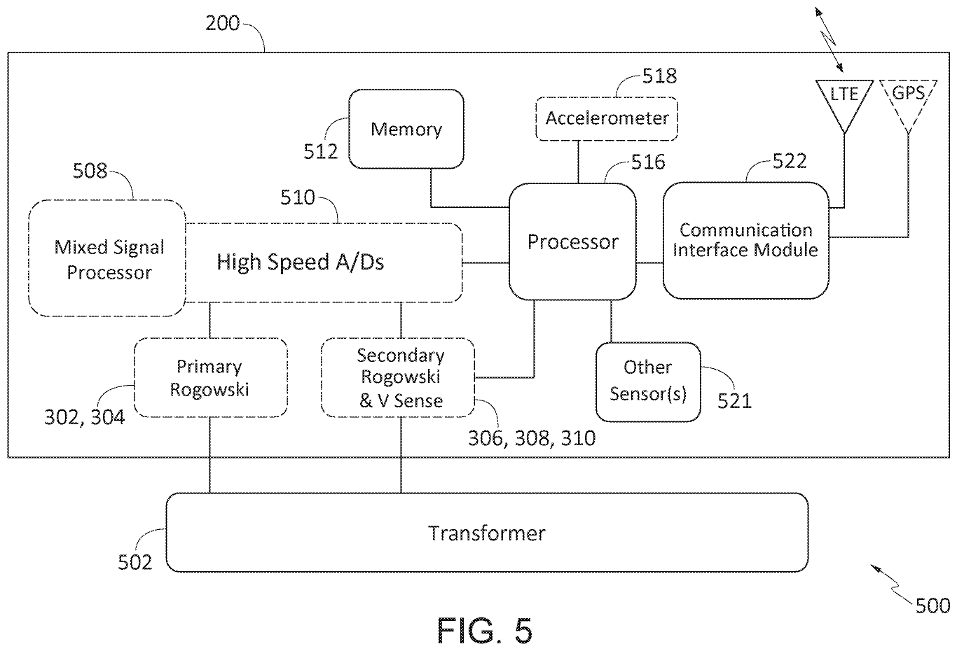

An exemplary distribution transformer system 500, as illustrated in block diagram form in FIG. 5, may include a number of separate components or components that form part of a number of integrated devices that include all or some of the functionality of the separate individual components. For example, the exemplary distribution transformer system 500 may include a distribution transformer 502 (e.g., an aerial distribution transformer 155 or a padmount distribution transformer 150) and a monitoring device, such as the monitoring device 200 described above. The monitoring device includes, inter alia, a processor 516, a communication interface module 522, non-transitory memory 512, and a wireless communication antenna (e.g., an LTE or 5G antenna). The monitoring device 200 may also include an optional Rogowski coil assemblies, which can include one or more primary terminal Rogowski coil assemblies 302, 304, one or more secondary terminal Rogowski coil assemblies 306, 308, 310 (which can further include voltage sensing), and one or more high-speed analog-to-digital converters 510. Where the monitoring device does not include secondary terminal Rogowski coil assemblies 306, 308, 310, the monitoring device includes voltage sensing cables (not shown) to enable secondary terminal voltages to be sensed by the voltage sensor(s) 201. The monitoring device 200 may further include an accelerometer 518 (such as a G-sensor), a global positioning system (GPS) antenna, and associated receiver and processing circuitry. The memory 512 stores instructions (e.g., software, firmware, machine code, object code, etc.) executable by the processor 516 to perform various computing and control operations as described herein.

In yet another embodiment, the monitoring device 200 may optionally include a mixed signal processor 508 designed for high accuracy measurement of power and energies in power line systems using Rogowski coils, current transformers, or shunt current sensors. When included, such a processor 508 can provide instantaneous voltage and current waveforms and calculate RMS values of voltages and currents, as well as active, reactive and apparent power and energies.

The hatch door 120 or the monitoring device 200 can further include one or more accelerometers 518 coupled to the one or more processors (516) for detection of sudden movement of one or more transformers (502) among a plurality of transformers in the system 500. The accelerometer 518 as well as some of the other devices (such as the analog-to-digital converter(s) 510 and secondary Rogowski Coil with voltage sense 506) can be coupled to a processor 516, such as a microcontroller. The processor 516 can send (or receive) the gathered data to a communication module 522 which supports communication via LTE and also able to receive and transmit GPS or other location data to a remote processor/server 402. In some embodiments, the communication module 522 can include a global positioning system receiver and in other embodiments a separate GPS receiver can be coupled to at least one or more transformers among the plurality of transformers to detect any sudden movement or acceleration (earthquake, tremor, crash impact, lightning strike, projectile impact, etc.). In some embodiments, the system can further monitor and transmit at least a corresponding waveform or data representative of the waveform for at least one or more of the transformers in such a system using the parameter sensors or Rogowski coil or coils (and a waveform capturing and processing device or display) as previously described. The system would generally be configured to generate an alert when at least the corresponding waveform (or certain data) is beyond a predetermined deviation from a reference waveform (or from reference data).

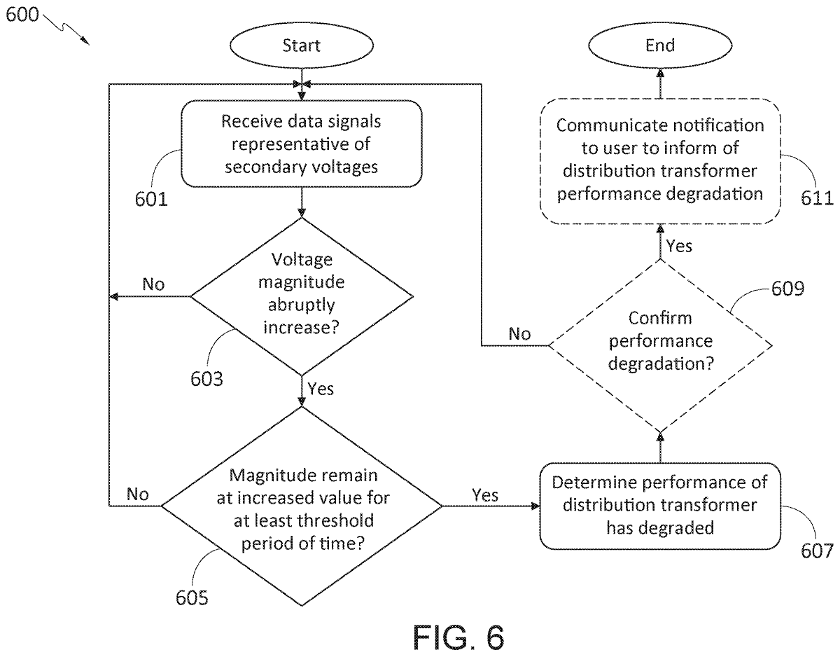

FIG. 6 is a logic flow diagram 600 of steps executed by a processor 402, 516 to predict performance degradation of a distribution transformer (e.g., a padmount distribution transformer 150, an aerial distribution transformer 155, a vault distribution transformer, etc.) in accordance with some exemplary embodiments of the present disclosure. According to the exemplary logic flow, the processor 402, 516 receives (601) data signals representative of voltages at one or more secondary terminals 156, 160 of the distribution transformer. The data signals may be representative of peak or root mean square (RMS) voltages at the secondary terminal(s) 156, 160 and be received over days, weeks, months, and years at preset or configurable reporting intervals (e.g., every N minutes or every M hours, where N and M are integers) programmed into the monitoring device 200. Where the data signals are received from a transformer monitoring device 200 located remotely from the processor 402 performing analysis of the data signals, the monitoring device 200 communicates the data signals to the processor 402 at the reporting time intervals (e.g., by wirelessly transmitting them to the remote processor 402 via a virtual private network established over a cellular or other communication system). Where the processor 516 performing analysis of the data signals is integrated into the monitoring device 200, the processor 516 may receive the data signals from an analog-to-digital converter 510 that converts the raw analog signals output from voltage sensor(s) 201 into the data signals. According to one exemplary embodiment, each Rogowski coil cable assembly 306, 310 connected to a secondary terminal 156, 160 includes a voltage sensing cable to enable a voltage senor 201 (voltage sensing circuit) in the monitoring device 200 to sense the voltage of the secondary terminal 156, 160 relative to the neutral terminal 158 of the transformer 155.

From the received data signals, the processor 402, 516 determines (603) whether a magnitude of a voltage at a secondary terminal 156, 160 abruptly increased. According to an exemplary embodiment, the processor 402, 516 determines that the magnitude of the voltage at the secondary terminal 156, 160 has abruptly increased if it has increased by at least ten percent above its nominal magnitude. For example, as illustrated in the exemplary graph 404a of secondary terminal voltages over time as shown on the exemplary customer dashboard 404 in FIG. 4, the voltage sensed at a secondary terminal 156 (Voltage 1) abruptly increased (e.g., stepped up) at the two dates and times indicated by dashed circles in the graph 404a.

When the processor 402, 516 determines that the magnitude of the voltage at the secondary terminal 156, 160 abruptly increased, the processor 401, 516 further determines (605) whether the magnitude of the voltage at the secondary terminal 156, 160 remained at the increased magnitude for at least a threshold period of time (e.g., at least thirty minutes, sixty minutes, six hours, twelve hours, or twenty-four hours). According to one exemplary embodiment, the threshold period of time is preferably a two-hour to four-hour window of time. For example, as illustrated in the exemplary graph 404a of secondary terminal voltages over time as shown on the exemplary customer dashboard 404 in FIG. 4, the sensed secondary terminal voltage at secondary terminal 156 remained at an increased magnitude after its first abrupt increase and then increased again within about 48 hours. As shown in the graph, the first increase in the secondary terminal voltage raised the voltage to the high end of the voltage's normal or nominal range and the second increase raised the voltage above its normal range. The voltage then remained at the increased magnitude outside of normal range.

When the processor 402, 516 determines that the voltage at the secondary terminal 156, 160 remains at the increased magnitude for at least the threshold period of time, the processor 402, 516 determines (607) that the performance of the distribution transformer has degraded. When the processor 402, 516 determines that either the magnitude of the voltage at the secondary terminal 156, 160 has not abruptly increased or such voltage magnitude did abruptly increase but did not remain at the increased magnitude for at least the threshold period of time, the processor 402, 516 concludes that the performance of the distribution transformer has not degraded.

Upon determining that the performance of the distribution transformer has degraded, the processor 402, 516 may optionally communicate (611) a notification of such performance degradation to a user (e.g., a utility or other operator (e.g., commercial or industrial entity that owns or operates its own distribution transformers)) that owns or controls the distribution transformer. For example, the processor 402 may post the notification on the user's panel/dashboard 404 of a web-based or mobile application or the processor 402, 516 may communicate the notification by email, text, or other means to the user.

Additionally or alternatively, the processor 402, 516 may optionally confirm (609) that the abrupt increase in secondary terminal voltage magnitude is predictive of performance degradation of the distribution transformer 150, 155 by analyzing other operational parameters of the distribution transformer 150, 155. For example, the processor 402, 516 may receive additional data signals representative of voltages (e.g., RMS or peak) at a primary terminal 152 of the distribution transformer, such as from the transformer monitoring device 200 or from one or more sensors 302, 304, 521 forming a part thereof or being physically or wirelessly coupled thereto. From the additional data signals, the processor 402, 516 may determine whether a magnitude of a voltage at the primary terminal 152 abruptly increased within a predetermined time window (e.g., within a few seconds) prior to the abrupt increase in the voltage at the secondary terminal 156, 160. In other words, the processor 402, 516 may determine whether the abrupt increase in the secondary terminal voltage was due to an abrupt increase in the primary terminal voltage. If the magnitude of the voltage at the primary terminal 152 did not abruptly increase within the predetermined time window prior to the abrupt increase in the voltage at the secondary terminal 156, 160, then the processor 402, 516 may confirm that the performance of the distribution transformer has degraded.

Alternatively or additionally, the processor 402, 516 may optionally analyze other non-voltage operational parameters of the distribution transformer 150, 155 (such as, for example, oil pressure, oil temperature, primary winding temperature, secondary winding temperature, and/or secondary current) to determine whether a magnitude of one or more of those parameters had an abrupt change (e.g., increase) within a time window (e.g., less than thirty minutes and possibly even less than a minute) of the abrupt increase in the voltage at the secondary terminal 156, 160. When the processor 402, 516 determines that the magnitude of at least one other operational parameter abruptly increased within the predetermined time window of the abrupt increase in the voltage at the secondary terminal 156, 160, the processor 402, 516 may confirm that performance of the distribution transformer has degraded (and the distribution transformer may be headed toward failure). When analyzing magnitudes of operational parameters other than voltage and current, the processor 402, 516 may compute or receive from the monitoring device 200 average magnitude values over a time period (e.g., minutes or hours) to account for any transient activity and, when analyzing voltage and current, the processor 402, 516 may compute or receive from the monitoring device 200 RMS values.

For example, referring again to the web application dashboard 404 as shown in FIG. 4, the dashboard also shows a graphs 404b of oil pressure over time, a graph 404 c of current (Current 1) and oil temperature over time for secondary terminal 156, and a graph 404d of current (Current 2) and oil temperature over time for secondary terminal 160. At the time of the secondary terminal voltage magnitude increase shown in graph 404a, the oil pressure and the oil temperature both increased significantly as shown by the circled areas in the respective graphs 404b, 404c. The rise in oil pressure and temperature contemporaneous with the increase in voltage magnitude at secondary terminal 156 confirms that the transformer 150, 155 has degraded performance and is likely to fail.

In some embodiments, as illustrated by FIG. 3A, the distribution transformer 100 is a pad-mounted distribution transformer, where at least the transformer monitoring device 200 and its associated sensors are positioned within a hatch defined by a housing of the pad-mounted distribution transformer, and where the alert informs the remote computing device that motion is occurring or has occurred or that a fire is occurring or has occurred in the hatch. In some embodiments, the accelerometer 201 can be directly mounted on the hatch 210 itself. In some embodiments the accelerometer 201 can include a wired or wireless link to the monitoring device 200 or to a remote computing device.

In some embodiments, as shown in FIG. 3A and FIG. 5, the monitoring device 200 and its external sensors may be incorporated directly into the distribution transformer 100 to form a smart transformer.

In the absence of any specific clarification related to its express use in a particular context, where the terms “substantial” or “about” in any grammatical form are used as modifiers in the present disclosure and any appended claims (e.g., to modify a structure, a dimension, a measurement, or some other characteristic), it is understood that the characteristic may vary by up to 30 percent. For example, an electronic device may be described as being mounted “substantially vertical,” In these cases, a device that is mounted exactly vertical is mounted along a “Y” axis and a “X” axis that is normal (i.e., 90 degrees or at right angle) to a plane or line formed by a “Z” axis. Different from the exact precision of the term, “vertical,” and the use of “substantially” or “about” to modify the characteristic permits a variance of the particular characteristic by up to 30 percent.

The terms “include” and “comprise” as well as derivatives thereof, in all of their syntactic contexts, are to be construed without limitation in an open, inclusive sense, (e.g., “including, but not limited to”). The term “or,” is inclusive, meaning “and/or.” The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Reference throughout this specification to “one embodiment” or “an embodiment” or “some embodiments” and variations thereof mean that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. As the context may require in this disclosure, except as the context may dictate otherwise, the singular shall mean the plural and vice versa.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items and one or more other alternative embodiments that include fewer than all of the associated items.

When so arranged as described herein, each computing device may be transformed from a generic and unspecific computing device to a combination device comprising hardware and software configured for a specific and particular purpose. When so arranged as described herein, to the extent that any of the inventive concepts described herein are found by a body of competent adjudication to be subsumed in an abstract idea, the ordered combination of elements and limitations are expressly presented to provide a requisite inventive concept by transforming the abstract idea into a tangible and concrete practical application of that abstract idea.

The various embodiments described above can be combined to provide further embodiments. Aspects of the embodiments can be modified, if necessary to employ concepts of the various patents, application and publications to provide further embodiments.

What is claimed is:

1. A method for predicting performance degradation of a distribution transformer in an electrical distribution system, the method comprising:
receiving, at a processor, data signals representative of voltages at one or more secondary terminals of the distribution transformer;
determining, by the processor from the received data signals, whether a magnitude of a voltage at a secondary terminal of the one or more secondary terminals abruptly increased to an increased magnitude;
determining, by the processor from the received data signals, whether the voltage at the secondary terminal remained at the increased magnitude for at least a threshold period of time; and
determining, by the processor, that performance of the distribution transformer has degraded when the magnitude of the voltage at the secondary terminal remained at the increased magnitude for at least the threshold period of time.

2. The method of claim 1, wherein the data signals are representative of root mean square (RMS) voltages at the one or more secondary terminals of the distribution transformer.

3. The method of claim 1, further comprising:
communicating, by the processor, a notification to a user to inform that performance of the distribution transformer has degraded.

4. The method of claim 1, further comprising:
detecting, by a monitoring device, the voltages at the one or more secondary terminals of the distribution transformer; and
communicating, by the monitoring device, the data signals to the processor, wherein the processor is located remotely from the monitoring device.

5. The method of claim 1, further comprising:
detecting, by a monitoring device, the voltages at the one or more secondary terminals of the distribution transformer, wherein the monitoring device includes the processor.

6. The method of claim 1, wherein the threshold period of time is at least thirty minutes.

7. The method of claim 1, further comprising:
receiving, at the processor, second data signals representative of voltages at a primary terminal of the distribution transformer;
determining, by the processor from the received second data signals, whether a magnitude of a voltage at the primary terminal abruptly increased within a predetermined time window prior to the abrupt increase in the voltage at the secondary terminal; and
confirming, by the processor, that performance of the distribution transformer has degraded when the magnitude of the voltage at the primary terminal did not abruptly increase within the predetermined time window prior to the abrupt increase in the voltage at the secondary terminal.

8. The method of claim 1, further comprising:
receiving, at the processor, second data signals representative of at least one other operational parameter of the distribution transformer;
determining, by the processor from the received second data signals, whether a magnitude of the at least one other operational parameter abruptly increased within a predetermined time window of the abrupt increase in the voltage at the secondary terminal; and
confirming, by the processor, that performance of the distribution transformer has degraded when the magnitude of the at least one other operational parameter abruptly increased within the predetermined time window of the abrupt increase in the voltage at the secondary terminal.

9. The method of claim 8, wherein the magnitude of the at least one other operational parameter is an average magnitude.

10. The method of claim 8, wherein the predetermined time window is less than thirty minutes.

11. The method of claim 1, wherein the data signals are communicated from a monitoring device collocated with the distribution transformer, the monitoring device monitoring at least the voltages at the one or more secondary terminals of the distribution transformer.

12. The method of claim 1, wherein the processor is located remotely from the distribution transformer and resides in a cloud environment.

13. The method of claim 1, wherein the abrupt increase in the voltage at the secondary terminal occurs within a one-hour to ten-hour window of time.

14. A system for monitoring a distribution transformer, the system comprising:
a monitoring device collocated with the distribution transformer, the monitoring device being configured to detect voltages at one or more secondary terminals of the distribution transformer and generate data signals representative of the detected secondary terminal voltages; and
a processor operable in accordance with stored operating instructions to:
receive the data signals;
determine, from the received data signals, whether a magnitude of a voltage at a secondary terminal of the one or more secondary terminals abruptly increased;
when a magnitude of a voltage at the secondary terminal abruptly increased, determine, from the received data signals, whether the magnitude of the voltage at the secondary terminal remained at the increased magnitude for at least a threshold period of time; and
determine that performance of the distribution transformer has degraded when the magnitude of the voltage at the secondary terminal remained at the increased magnitude for at least the threshold period of time.

15. The system of claim 14, wherein the processor forms part of the monitoring device.

16. The system of claim 14, wherein the monitoring device is further configured to detect voltages at a primary terminal of the distribution transformer and generate second data signals representative of the detected primary terminal voltages; and
wherein the processor is further operable in accordance with stored operating instructions to:
receive the second data signals;
determine, from the received second data signals, whether a magnitude of a voltage at the primary terminal abruptly increased within a predetermined time window prior to the abrupt increase in the voltage at the secondary terminal; and
confirm that performance of the distribution transformer has degraded when the magnitude of the voltage at the primary terminal did not abruptly increase within the predetermined time window prior to the abrupt increase in the voltage at the secondary terminal.

17. The system of claim 14, wherein the monitoring device is further configured to detect at least one other operational parameter of the distribution transformer and generate second data signals representative of the at least one other operational parameter; and
wherein the processor is further operable in accordance with stored operating instructions to:
receive the second data signals;
determine, from the received second data signals, whether a magnitude of the at least one other operational parameter abruptly increased within a predetermined time window of the abrupt increase in the voltage at the secondary terminal; and
confirm that performance of the distribution transformer has degraded when the magnitude of the at least one other operational parameter abruptly increased within the predetermined time window of the abrupt increase in the voltage at the secondary terminal.

18. The system of claim 14, wherein the abrupt increase in the voltage at the secondary terminal occurs within a two-to-four hour window of time.

19. The system of claim 14, wherein the threshold period of time is at least twelve hours.

20. The system of claim 14, wherein the processor is located remotely from the monitoring device and resides in a cloud environment, and wherein the monitoring device is further configured to wirelessly communicate the data signals to the processor.

21. An apparatus for monitoring a distribution transformer, the apparatus comprising:
at least one voltage sensor configured to detect voltages at one or more secondary terminals of the distribution transformer and generate signals representative of the detected secondary terminal voltages;
one or more analog-to-digital converters that convert the signals generated by the at least one voltage sensor into data signals;
a processor operable in accordance with stored operating instructions to:
receive the data signals;
determine, from the data signals, whether a magnitude of a voltage at a secondary terminal of the one or more secondary terminals abruptly increased;
when a magnitude of a voltage at the secondary terminal abruptly increased, determine, from the data signals, whether the magnitude of the voltage at the secondary terminal remained at the increased magnitude for at least a threshold period of time; and
determine that performance of the distribution transformer has degraded when the magnitude of the voltage at the secondary terminal remained at the increased magnitude for at least the threshold period of time.
